(19) United States
(12) Patent Application Publication
(10) Pub. No.: US 2026/0182161 A1
(43) Pub. Date: Jun. 25, 2026

(54) DISPLAY DEVICE

(71) Applicant: LG Display Co., Ltd., Seoul (KR)

(72) Inventors: Jooho LEE, Goyang-si (KR); Byoungjin JEON, Gimpo-si (KR); KwangSoo KIM, Incheon (KR); Wooyeong JANG, Seoul (KR)

(73) Assignee: LG Display Co., Ltd., Seoul (KR)

(21) Appl. No.: 19/319,271

(22) Filed: Sep. 4, 2025

(30) Foreign Application Priority Data
Dec. 24, 2024 (KR) 10-2024-0196186

(51) Int. Cl. H10K 59/123; H10K 102/00

(52) U.S. Cl. CPC H10K 59/123; H10K 2102/311

(57) ABSTRACT

Provided is a display device including a display panel having a non-bending area and a bending area. The non-bending area includes an active area in which a plurality of light emitting diodes is disposed and a non-active area which encloses the active area. The bending area extends from one side of the non-active area. A polarization plate is disposed on the display panel in the non-bending area, and a first adhesive layer is disposed between the display panel and the polarization plate in the non-bending area. A first protection member is disposed on the display panel in the bending area. The polarization plate includes at least one first contact hole in a first area of the non-active area between the active area and the bending area, and an end portion of the first protection member extends into the first area and is present in the at least one first contact hole.

### CROSS-REFERENCE TO RELATED APPLICATIONS

This application claims the priority of Korean Patent Application No. 10-2024-0196186 filed on Dec. 24, 2024, in the Korean Intellectual Property Office, the disclosure of which is incorporated herein by reference.

### BACKGROUND

### Technical Field

The present disclosure relates to a display device, and more particularly, to a display device which suppresses a panel crack.

### Description of the Related Art

An image display device which visually implements various electrical information signals on a screen is a core technology of an information and communication era and an application range thereof is diversified not only to a computer monitor and a TV, but also to a personal mobile device.

A variety of display devices with excellent performance in small thickness, light-weight, and low power consumption are being developed and examples thereof include a liquid crystal display device (LCD), a field emission display device (FED), and an organic light emitting display device (OLED).

Recently, a display device which is manufactured by forming a display unit and a wiring line on a flexible substrate, such as plastic which is a flexible material so as to be stretchable in a specific direction and changed in various forms is getting attention.

### BRIEF SUMMARY

Various embodiments of the present disclosure provide a display device which reduces a stress applied to a display panel due to a thermal deformation.

Various embodiments of the present disclosure provide a display device which minimizes a stress applied to a display panel to improve reliability.

According to the present disclosure, one end portion of a protection member which covers the display panel in the bending area is fastened with a contact hole included in an outer peripheral portion of a polarization plate to reduce a stress which is applied to the display panel due to a thermal deformation of the polarization plate.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device includes a display panel which includes a non-bending area including an active area in which a plurality of light emitting diodes is disposed and a non-active area which encloses the active area and a bending area extending from one side of the non-active area. The display device further includes a polarization plate disposed on the display panel in the non-bending area. The display device further includes a first adhesive layer disposed between the display panel and the polarization plate in the non-bending area. The display device further includes a first protection member disposed on the display panel in the bending area. The polarization plate includes at least one first contact hole in a first area of the non-active area between the active area and the bending area and one end portion of the first protection member extends to a part of the first area to be filled in the at least one first contact hole.

Other detailed matters of the exemplary embodiments are included in the detailed description and the drawings.

According to the present disclosure, one end portion of a protection member which covers a side portion of the display panel in an area other than the bending area is fastened with a contact hole included in an outer peripheral portion of a polarization plate to reduce a stress which is applied to the display panel due to a thermal deformation of the polarization plate.

According to the present disclosure, even though the polarization plate is exposed to repeated temperature change to be repeatedly thermally expanded and contacted, the separation between the polarization plate and the protection members or the polarization plate and the display panel is suppressed. By doing this, the stress applied to the display panel is relieved to suppress a crack defect of the display panel.

According to the present disclosure, the reliability of the display device is ensured to improve the lifespan and achieve low power driving.

The effects according to the present specification are not limited to the above-mentioned effects, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram of a display device according to an exemplary embodiment of the present disclosure;

FIG. 2 is a plan view of a display panel according to an exemplary embodiment of the present disclosure;

FIG. 3 is a perspective view illustrating a bent state of a display panel according to an exemplary embodiment of the present disclosure;

FIG. 4 is a driving circuit diagram of a sub pixel according to an exemplary embodiment of the present disclosure;

FIG. 5 is a cross-sectional view taken along I-I′ of FIG. 2;

FIG. 6 is a cross-sectional view taken along II-II′ of FIG. 2;

FIG. 7 is a cross-sectional view of a part of a display device according to an exemplary embodiment of the present disclosure;

FIG. 8 is a plan view of a display panel according to another exemplary embodiment of the present disclosure;

FIG. 9 is a plan view of a display panel according to still another exemplary embodiment of the present disclosure;

FIG. 10 is a cross-sectional of another part of a display device according to an exemplary embodiment of the present disclosure; and

FIG. 11 is a plan view of a display panel according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

In the present specification, a “display apparatus” may include a display apparatus which includes a display panel and a driver for driving the display panel, in a narrow sense, such as a liquid crystal module (LCM), an organic light emitting module (OLED module), and a quantum dot module. Further, the “display apparatus” may further include a set electronic apparatus or a set apparatus (or a set device) which is a complete product or a final product including an LCM, an OLED module, a QD module, etc., such as a notebook computer, a television, or a computer monitor, an automotive display apparatus or equipment display apparatus including another type of vehicle and a mobile electronic apparatus including a smart phone or an electronic pad.

Accordingly, the display apparatus of the present disclosure may include not only a display apparatus itself in a narrow sense such as an LCM, an OLED module, a QD module, etc., but also an applied product or a set apparatus which is a final consumer device including the LCD, the OLED module, the QD module, etc.

Further, in some cases, the LCM, the OLED module, or the QD module which is configured by a display panel and a driver may be represented as “a display apparatus” in a narrow sense and an electronic device as a complete product including the LCM, the OLED module, and the QD module may be represented as a “set apparatus”. For example, the display apparatus in the narrow sense includes a liquid crystal (LCD) display panel, an OLED display panel, or a quantum dot display panel and a source PCB which is a controller for driving the display panel. In contrast, the set apparatus may be a concept further including a set PCB which is a set controller which is electrically connected to the source PCB to control the entire set apparatus.

As a display panel used in the exemplary embodiment of the present disclosure, any type of display panel such as a liquid crystal display panel, an organic light emitting diode (OLED) display panel, a quantum dot (QD) display panel, and an electroluminescent display panel may be used. The display panel of the present exemplary embodiment is not limited to a specific display panel in which a bezel is bent with a flexible substrate for the organic light emitting diode (OLED) display panel and a back plate support structure therebelow. Further, a display panel used for the display apparatus according to the exemplary embodiment of the present disclosure is not limited to a shape or a size of the display panel.

For example, when the display panel is an OLED display panel, the display panel may include a plurality of gate lines, data lines, and pixels formed at intersecting areas of the gate lines and/or data lines. Further, the display panel may be configured to include an array including a thin film transistor which is an element to selectively apply a voltage to each pixel, a light emitting diode layer on the array, an encapsulation substrate or an encapsulation layer, and the like disposed on the array so as to cover the light emitting diode layer. The encapsulation layer may protect the thin film transistor the light emitting diode layer, and the like from external impacts and may suppress the permeation of moisture or oxygen into the light emitting diode layer. Further, a layer formed on the array may include an inorganic light emitting layer, for example, a nano-sized material layer quantum dots, or the like.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

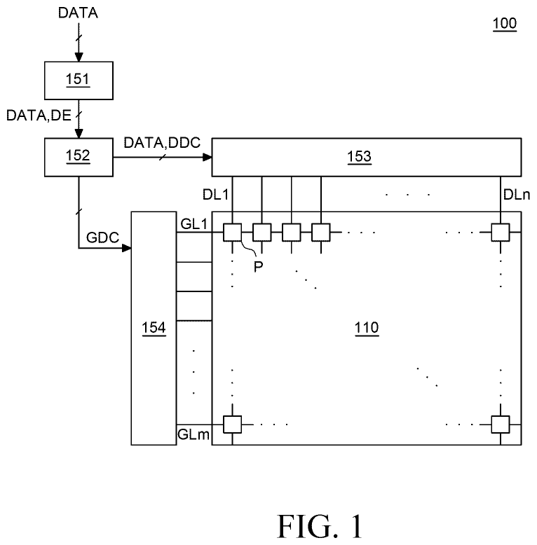

FIG. 1 is a block diagram of a display device according to an exemplary embodiment of the present disclosure.

Referring to FIG. 1, a display device 100 according to an exemplary embodiment of the present disclosure may include an image processor 151, a timing controller 152, a data driver 153, a gate driver 154, and a display panel 110.

The image processor 151 may output a data signal DATA supplied from the outside and a data enable signal DE. The image processor 151 may output one or more of a vertical synchronization signal, a horizontal synchronization signal, and a clock signal in addition to the data enable signal DE.

The timing controller 152 is supplied with the data signal DATA together with a driving signal including the data enable signal DE or the vertical synchronization signal, the horizontal synchronization signal, and the clock signal, from the image processor 151. The timing controller 152 may output a gate timing control signal GDC for controlling an operation timing of the gate driver 154 and a data timing control signal DDC for controlling an operation timing of the data driver 153, based on the driving signal.

The data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn. The data driver 153 may be formed as an integrated circuit (IC).

The gate driver 154 may output the gate signal while shifting a level of the gate voltage, in response to the gate timing control signal GDC supplied from the timing controller 152. The gate driver 154 may output the gate signal through gate lines GL1 to GLm. The gate driver 154 may be formed as an IC or be formed in the display panel DP in a gate in panel (GIP) manner.

The data driver 153 and the gate driver 154 may be implemented as one or more integrated circuits and from the viewpoint of electrical connection with the display panel 110, may be implemented as a chip on glass (COG) type, a chip on film (COF) type, or a tape carrier package (TCP) type.

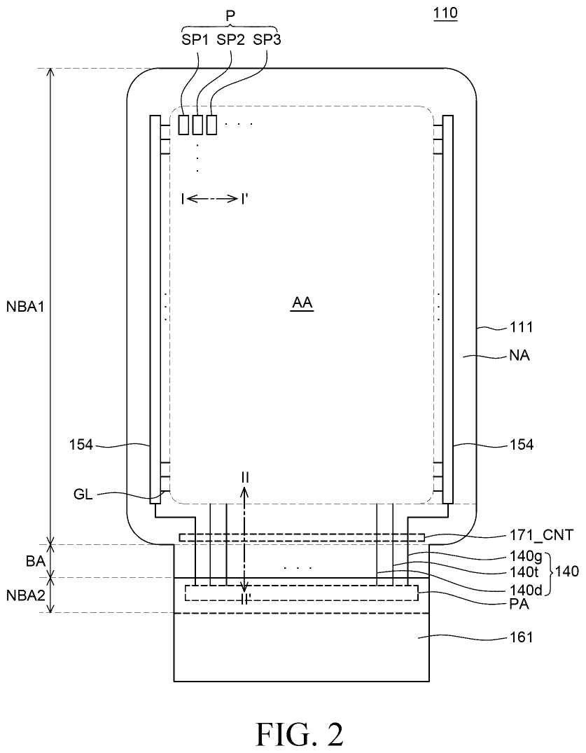

FIG. 2 is a plan view of a display panel according to an exemplary embodiment of the present disclosure.

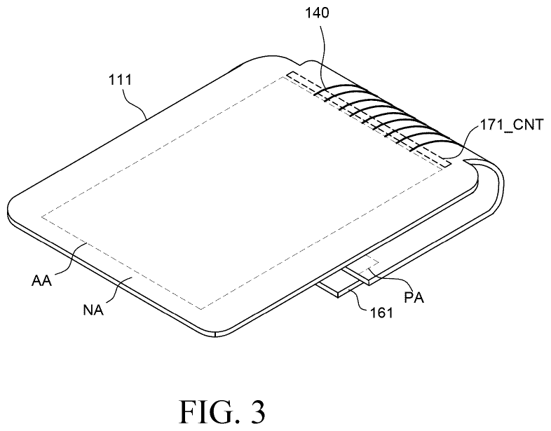

FIG. 3 is a perspective view illustrating a bent state of a display panel according to an exemplary embodiment of the present disclosure.

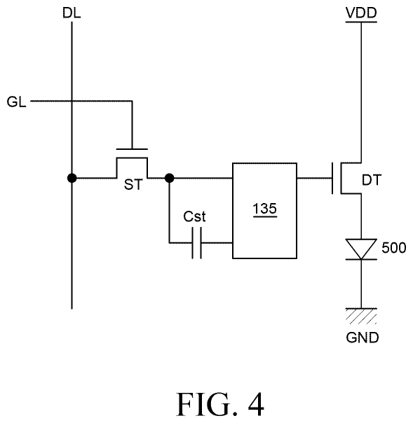

FIG. 4 is a driving circuit diagram of a sub pixel according to an exemplary embodiment of the present disclosure.

Referring to FIG. 2, the display panel 110 of the display device 100 according to the exemplary embodiment of the present disclosure may include a substrate 111 on which a light emitting diode which implements an image, a circuit which drives the light emitting diode, a wiring line and a component are disposed.

The display panel DP includes a plurality of pixels P and each of the plurality of pixels P emits light in response to the data signal DATA and the gate signal supplied from the data driver 153 and the gate driver 154, respectively, to display images.

One pixel P may be configured by a plurality of sub pixels. One pixel P may include three or more sub pixels which emit light having wavelengths which implement different colors. For example, in the display device 100 according to the exemplary embodiment of the present disclosure, one pixel P may include three sub pixels SP1, SP2 and SP3 which emit red light, green light, and blue light. However, the number of sub pixels included in one pixel P is not limited and for example, a sub pixel which emits white light may be further included, in addition to the sub pixels which emit red light, green light, and blue light. The sub pixel may have one or more different emission areas according to an emission characteristic.

Each of the plurality of sub pixels SP may include a light emitting diode and a pixel driving circuit which controls an amount of current flowing through the light emitting diode.

Referring to FIG. 4, a pixel driving circuit may include a switching transistor ST, a driving transistor DT, a compensation circuit 135, and a light emitting diode 500.

The light emitting diode 500 may operate to emit light in accordance with a driving current formed by the driving transistor DT.

The switching transistor ST may perform a switching operation such that a data signal supplied through the data line DL is stored in a capacitor CST as a data voltage in response to a gate signal supplied through the gate line GL.

The driving transistor DT may operate to flow a constant driving current between a high potential power line VDD and a low potential power line GND in response to a data voltage stored in the capacitor CST.

For example, when the display device 100 is an organic light emitting display device, the sub pixel may include a light emitting diode which includes an anode electrode, an emitting layer on the anode electrode, and a cathode electrode on the emitting layer. At this time, the light emitting diode may include an organic emitting layer as an emitting layer and further include a hole transport layer, a hole injection layer, an electron injection layer, and an electron transport layer together with the organic emitting layer. In one exemplary embodiment of the present disclosure, it is assumed that the display device 100 is an organic light emitting display device, but is not limited thereto.

In the above description, it has been described that the pixel driving circuit is configured with a 2T (transistor) 1C (capacitor) structure including one switching transistor, one driving transistor, and one capacitor as an example. As another example, the pixel driving circuit may further include a compensation circuit 135. The compensation circuit 135 is a circuit for compensating for a threshold voltage of the driving transistor and may include one or more compensating thin film transistors and compensating capacitors. Configurations and structures of the compensating thin film transistors and the compensating capacitors are not limited, but may vary depending on a compensating method.

Referring to FIG. 2, the display panel 110 of the display device 100 according to the exemplary embodiment of the present disclosure may include a circuit element 161 which supplies a driving signal to the active area AA. Driving signals supplied through the circuit element 161, such as a gate signal, a data signal, and a touch driving signal, may be supplied to the gate lines, the data lines, and the touch electrodes of the active area AA through the connection line 140. The circuit element 161 may be a chip on film (COF) in which a driving integrated circuit (IC) is mounted in a flexible film and may be implemented as a COG type in which pads are directly bonded on the substrate 111 by a chip on glass (COG) process. Further, the circuit element 161 may be a flexible circuit, such as a flexible flat cable (FFC) or a flexible printed circuit (FPC).

The substrate 111 of the display panel 110 may include an active area AA and a non-active area NA at the outside of the active area AA. The non-active area NA may include a first non-active area which encloses around the active area AA, a bending area BA extending from one side of the first non-active area, and a second non-active area extending from the bending area BA. Even though in FIG. 2, a structure is shown in which the first non-active area encloses an entire surface of the active area AA as an example, but is not limited thereto so that the first non-active area may be located only in a partial area at the outside of the active area AA. Further, the substrate 111 of the display panel 110 may also be defined by a first non-bending area NBA1 including the active area AA and the first non-active area, a bending area BA extending from the first non-bending area NBA1, and a second non-bending area NBA2 extending from the bending area BA.

In FIG. 2, a state before bending of the substrate 111 is illustrated.

The non-active area NA of the substrate 111 is an area where various wiring lines and circuits for driving the sub pixels SP1, SP2, and SP3 disposed in the active area AA are disposed. The non-active area NA is not an area where the images are displayed so that the non-active area does not need to be visible from a front surface of the display panel 110. Therefore, a partial area of the non-active area NA of the substrate 111 may be bent toward the rear surface of the display panel 110. For example, as illustrated in FIG. 3, the bending area BA in one edge of the substrate 111 may be bent toward a rear direction of the display panel 110 to have a predetermined curvature.

The second bending area NBA2 of the substrate 111 may include a pad area PA in which a plurality of pad units is disposed and the plurality of pad units may include pads (for example, metal patterns) which are connected to an external module, for example, a flexible printed circuit board (FPCB) and a chip on film (COF). The plurality of pad units is electrically connected to the sub pixels and may include a display pad unit including a plurality of signal pads which transmits various signals and a power to drive sub pixels. When the bending area BA of the substrate 111 is bent toward the rear direction of the display panel 110, a pad area PA may be located so as to overlap the active area AA on a rear surface of the display panel 110. By doing this, the non-active area NA may be reduced while ensuring an area for the wiring line and the driving circuit.

A plurality of connection lines 140 may be disposed between the active area AA and the second non-active area of the substrate 111, that is, in the first non-active area and the bending area BA.

The connection line 140 includes a plurality of gate connection lines 140g which transmits a signal (for example, a voltage) from the external module to the active area AA or a gate driving unit included in the gate driver 154. The gate driving unit supplies a gate signal to a thin film transistor of a pixel driving circuit and may include various gate driving circuits. In the display device 100 according to the exemplary embodiment of the present disclosure, the gate driving unit may be a gate-in-panel (GIP) in which the gate driving circuits are directly formed on the substrate 111.

The connection line 140 includes a plurality of data connection lines 140d which transmits a data signal for displaying images supplied from the external module to the active area AA.

Further, the connection line 140 may further include power connection lines which transmit various voltages, such as a high potential voltage and a low potential voltage, in addition to the gate signal and the data signal. The power connection line transmits a voltage supplied from the external module to the active area AA and may be connected to a low potential voltage line, a high potential voltage line, a gate low voltage line and/or a gate high voltage line included in the gate driving unit, but is not limited thereto.

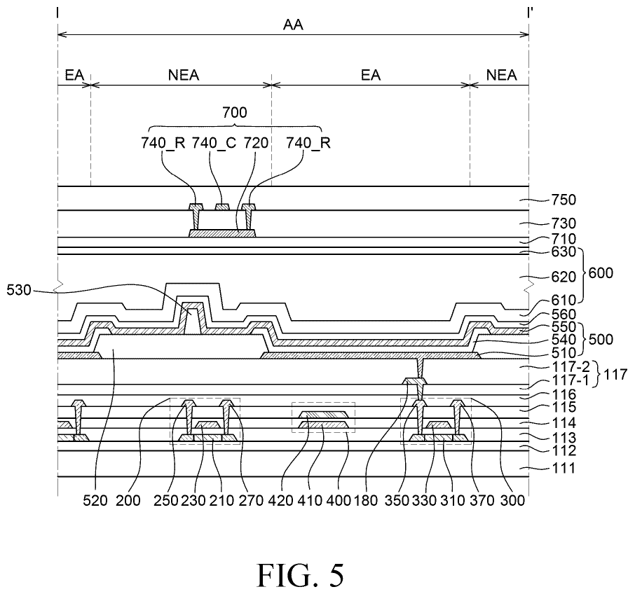

In the meantime, a touch sensing layer may be disposed above an encapsulation layer which covers a light emitting diode of the sub pixel, on the active area AA of the substrate 111. In the touch sensing layer, a touch sensing unit including a plurality of touch electrodes is disposed and the encapsulation layer and the touch sensing layer will be described in more detail with reference to FIG. 5.

A plurality of pad units disposed in the pad area PA of the substrate 111 may further include a touch pad unit which is electrically connected to a plurality of touch electrodes of the touch sensing layer. The touch pad unit may include a plurality of touch pads.

The connection line 140 includes a plurality of touch connection lines 140t which electrically connects the plurality of touch electrodes and touch pads.

The connection line 140 may be formed of a conductive material and may be formed of a conductive material having an excellent ductility to reduce the crack generated at the time of bending the substrate 111.

The circuit element 161 may be attached to the second non-bending area NBA2 of the substrate 111. The circuit element 161 may be bonded to the second non-bending area NBA2 of the substrate 111 so as to overlap the pad area PA of the substrate 111.

Hereinafter, a structure of a sub pixel disposed in the active area AA of the display panel 110 which has been described in FIG. 2 will be described in more detail with reference to FIG. 5.

FIG. 5 is a cross-sectional view taken along I-I′ of FIG. 2.

Referring to FIG. 5, on the substrate 111, a light emitting diode 500 for displaying images and a plurality of first thin film transistors 200 and a second thin film transistor 300 for driving the light emitting diode 500 may be disposed.

The substrate 111 may support various components of the display device.

The substrate 111 may be formed of a glass or a plastic material having flexibility.

A first insulating layer 112 may be disposed on the substrate 111. The first insulating layer 112 may be disposed on the entire surface of the substrate 111. The first insulating layer 112 may block a material in the substrate 110 from moving to the thin film transistor or the semiconductor layer during a deposition process.

A first thin film transistor 200 and a second thin film transistor 300 may be disposed on the first insulating layer 112.

The first thin film transistor 200 may include a first semiconductor layer 210, a first gate electrode 230, a first source electrode 250, and a first drain electrode 270.

The second thin film transistor 300 may include a second semiconductor layer 310, a second gate electrode 330, a second source electrode 350, and a second drain electrode 370.

In the display device 100 according to the exemplary embodiment of the present disclosure, the first thin film transistor 200 may be a switching thin film transistor and the second thin film transistor 300 may be a driving thin film transistor, but are not limited thereto.

The first semiconductor layer 210 of the first thin film transistor 200 and the second semiconductor layer 310 of the second thin film transistor 300 may be disposed on the first insulating layer 112.

The first semiconductor layer 210 and the second semiconductor layer 310 may be formed of polycrystalline semiconductor, but are not limited thereto. The first semiconductor layer 210 and the second semiconductor layer 310 may be formed of oxide semiconductor, but are not limited thereto.

A second insulating layer 113 may be disposed on the first semiconductor layer 210 and the second semiconductor layer 310. The second insulating layer 113 may be disposed on the entire area of the substrate 111. The second insulating layer 113 is disposed between the first semiconductor layer 210 and the first gate electrode 230 to insulate the first semiconductor layer 210 and the first gate electrode 230 from each other.

The first gate electrode 230 of the first thin film transistor 200 and the second gate electrode 330 of the second thin film transistor 300 may be disposed on the second insulating layer 113. The first gate electrode 230 may be disposed so as to overlap the first semiconductor layer 210 and the second gate electrode 330 may be disposed so as to overlap the second semiconductor layer 310.

Further, a storage capacitor 400 may be disposed on the second insulating layer 113. The storage capacitor 400 may include a first capacitor electrode 410 and a second capacitor electrode 420. The storage capacitor 400 may store a data voltage applied through a data line for a predetermined period to supply the data voltage to the first electrode 510.

The first capacitor electrode 410 of the storage capacitor 400 may be disposed on the second insulating layer 113. For example, the first capacitor electrode 410 may be disposed on the same layer as the first gate electrode 230 and the second gate electrode 330 and may be formed by the same process as the first gate electrode 230 and the second gate electrode 330.

A third insulating layer 114 may be disposed on the first gate electrode 230, the second gate electrode 330, and the first capacitor electrode 410. The third insulating layer 114 may be disposed on the entire area of the substrate 111. The third insulating layer 114 may be disposed between each of the first source electrode 250 and the first drain electrode 270 and the first gate electrode 230 to insulate each of the first source electrode 250 and the first drain electrode 270 from the first gate electrode 230. Further, the third insulating layer 114 may be disposed between each of the second source electrode 350 and the second drain electrode 370 and the second gate electrode 330 to insulate each of the second source electrode 350 and the second drain electrode 370 from the second gate electrode 330.

The second capacitor electrode 420 of the storage capacitor 400 may be disposed on the third insulating layer 114 so as to overlap the first capacitor electrode 410.

A fourth insulating layer 115 may be disposed on the second capacitor electrode 420. The fourth insulating layer 115 may be disposed on the entire area of the substrate 111. The fourth insulating layer 115 may be disposed between each of the first source electrode 250 and the first drain electrode 270 and the first gate electrode 230 to insulate each of the first source electrode 250 and the first drain electrode 270 from the first gate electrode 230. Further, the fourth insulating layer 115 may be disposed between each of the second source electrode 350 and the second drain electrode 370 and the second gate electrode 330 to insulate the second source electrode 350 and the second drain electrode 370 from the second gate electrode 330.

The first source electrode 250 and the first drain electrode 270 may be disposed on the fourth insulating layer 115 and the second source electrode 350 and the second drain electrode 370 may be disposed on the fourth insulating layer 115.

Each of the first source electrode 250 and the first drain electrode 270 may be electrically connected to the first semiconductor layer 210 through the hole formed in each of the second insulating layer 113, the third insulating layer 114, and the fourth insulating layer 115. Further, each of the second source electrode 350 and the second drain electrode 370 may be electrically connected to the second semiconductor layer 310 through the hole formed in each of the second insulating layer 113, the third insulating layer 114, and the fourth insulating layer 115.

A fifth insulating layer 116 may be disposed on the first source electrode 250, the first drain electrode 270, the second source electrode 350, and the second drain electrode 370. The fifth insulating layer 116 may be disposed on the entire area of the substrate 111. The fifth insulating layer 116 may protect the first thin film transistor 200 and the second thin film transistor 300.

The protection layer 117 may be disposed on the fifth insulating layer 116. For example, the protection layer 117 may be an insulating layer or a planarization layer, but is not limited thereto. The protection layer 117 may protect the thin film transistor disposed therebelow and relieve or planarize a step due to various patterns.

As illustrated in FIG. 5, the protection layer 117 may include a first protection layer 117-1 and a second protection layer 117-2. For example, the first protection layer 117-1 may be a sixth insulating layer and the second protection layer 117-2 may be a seventh insulating layer, but are not limited thereto.

A part of the connection electrode 180 may be disposed in a hole formed in the first protection layer 117-1. Further, a part of the first electrode 510 of the light emitting diode layer 500 may be disposed in a hole of the second protection layer 117-2 disposed on the first protection layer 117-1 and the connection electrode 180. Therefore, the first thin film transistor 300 and the first electrode 510 may be electrically connected through the connection electrode 180.

The connection electrode 180 may be further disposed on the first protection layer 117-1. One end (or a part or one side) of the connection electrode 180 may be connected to the second thin film transistor 300 and the other end (or the other part or the other side) of the connection electrode 180 may be connected to the first electrode 510 of the light emitting diode layer 500.

The light emitting diode 500 may be disposed on the protection layer 117. The light emitting diode 500 may include a first electrode 510, an organic layer 540, and a second electrode 550.

The first electrode 510 of the light emitting diode 500 may be disposed on the second protection layer 117-2. The first electrode 510 may supply holes to the organic layer 540 and be formed of a conductive material having a high work function. The first electrode may be an anode electrode, but is not limited thereto.

A bank 520 may be disposed on the first electrode 510 and the protection layer 117.

The bank 520 may divide the plurality of sub pixels and define (or divide) an emission unit in which light is emitted and a non-emission unit in which light is not emitted. The bank 520 may be disposed in the non-emission unit and have a bank hole which exposes the emission unit and the first electrode 510. The bank 520 may be disposed so as to cover an end (or a partial area) of the first electrode 510. The bank 520 may minimize the glare phenomenon and suppress the color mixture caused at various viewing angles.

At least one spacer 530 may be disposed on the bank 520. The spacer 530 may suppress the damage of the organic layer 540 during the process of the organic layer 540 and minimize the breakage of the display device 100 caused by the external shocks.

The organic layer 540 may be disposed on the first electrode 510 and the bank 520. The organic layer 540 may include an emitting layer EML which emits light so as to allow each of the plurality of sub pixels to emit light with a specific color. For example, the emitting layer may include one of a red light emitting layer which emits red light, a green light emitting layer which emits green light, a blue light emitting layer which emits blue light, and a white light emitting layer. At this time, when the organic layer 540 includes the white emitting layer, a color filter for converting white light from the white emitting layer into another color light may be disposed above the organic layer 540.

The second electrode 550 may be disposed on the organic layer 540. The second electrode 550 may supply electrons to the organic layer 540 and may be formed of a conductive material having a low work function. The second electrode may be a cathode electrode, but is not limited thereto.

An encapsulation unit 600 may be disposed on the second electrode 550. The encapsulation unit 600 may protect the organic layer 540 from moisture, oxygen, or foreign materials from the outside. The encapsulation unit 600 may include a first encapsulation layer 610, a second encapsulation layer 620, and a third encapsulation layer 630. The first encapsulation layer 610, the second encapsulation layer 620, and the third encapsulation layer 630 may be alternately laminated, but are not limited thereto. The first encapsulation layer 610 and the third encapsulation layer 630 may be formed of at least one inorganic material, among silicon nitride (SiNx), silicon oxide (SiOx), or aluminum oxide (AlyOz), but are not limited thereto. The second encapsulation layer 620 may cover foreign materials or particles which may be generated during the manufacturing process of the display panel 110 and planarize a surface of the first encapsulation layer 610. The second encapsulation layer 620 may be an organic material, for example, a polymer such as silicon oxy carbon (SiOCz), epoxy, polyimide, polyethylene, or acrylate, but is not limited thereto.

A touch sensing unit 700 may be disposed on the encapsulation unit 600. The touch sensing unit 700 may include a first touch electrode 740_R, a first touch connection electrode 720, a second touch electrode, and a second touch connection electrode 740_C. Parts of the first touch electrode 740_R, the first touch connection electrode 720, the second touch electrode, and the second touch connection electrode 740_C may be disposed so as to overlap the bank 520.

The first touch electrode 740_R, the second touch electrode, the first touch connection electrode 720, and the second touch connection electrode 740_C may be formed with a mesh pattern in which metal lines intersect each other. The mesh pattern may have a rhombic shape. Further, the shape of the mesh pattern may be a rectangle, a pentagon, a hexagon, a circle, or an oval, but is not limited thereto.

A touch buffer layer 710 may be disposed on the encapsulation unit 600. The touch buffer layer 710 may block a liquid chemical (developer or etchant) used during the process of manufacturing a touch sensing unit 700 or moisture from the outside from being permeated into the light emitting diode layer 500 including an organic material. Further, the short-circuit of metals of a plurality of touch electrodes disposed above the touch buffer layer 710 due to the external shock may be suppressed and an interference signal which may be generated while driving the touch sensing unit 700 may be blocked. For example, the touch buffer layer 710 may be a touch buffer layer, a second buffer layer, or an eighth insulating layer, but is not limited thereto.

The first touch connection electrode 720 may be disposed on the touch buffer layer 710. For example, the first touch connection electrode 720 may be disposed between first touch electrodes 740_R which are adjacent to each other in the first direction to electrically connect first touch electrodes 740_R which are spaced apart from each other. The first touch connection electrode 720 may be disposed so as to overlap the second touch connection electrode 740_C which connects the second touch electrodes which are adjacent in the second direction which intersects the first direction. The first touch connection electrode 720 and the second touch connection electrode 740_C may be formed on different layers to be electrically insulated.

A touch insulating layer 730 may be disposed on the touch buffer layer 710 and the first touch connection electrode 720. For example, the touch insulating layer 730 may be a ninth insulating layer, but is not limited thereto. The touch insulating layer 730 may electrically insulate the second touch electrode and the second touch connection electrode 740_C.

The first touch electrode 740_R, the second touch electrode, and the second touch connection electrode 740_C may be disposed on the touch insulating layer 730. The first touch electrode 740_R and the second touch electrode may be disposed to be spaced apart from each other with a predetermined interval. For example, the first touch electrodes 740_R which are adjacent in the first direction may be spaced apart from each other and be connected to the first touch connection electrode 720 through a hole of the touch insulating layer 730. Further, the second touch electrodes which are adjacent in the second direction intersecting the first direction may be spaced apart from each other to be connected by the second touch connection electrode 740_C formed on the same layer. For example, the second touch connection electrode 740_C may be formed to extend from the second touch electrode, but is not limited thereto. The first touch electrode 740_R, the second touch electrode, and the second touch connection electrode 740_C may be formed by the same process.

A protection layer 750 may be disposed on the first touch electrode 740_R, the second touch electrode, and the second touch connection electrode 740_C. For example, the protection layer 750 may be a planarization layer, a touch planarization layer, a tenth insulating layer, or a third protection layer, but is not limited thereto.

A touch driving circuit which is mounted in the circuit element 161 may receive a touch sensing signal from the first touch electrode 740_R. Further, the touch driving circuit may transmit a touch driving signal from the second touch electrode.

In the display device 100 according to the exemplary embodiment of the present disclosure, a polarization plate and a cover member may be disposed on the touch sensing unit 700. For example, the polarization plate 171 and the cover member 175 to be described below may be disposed on the protection layer 750 of FIG. 5.

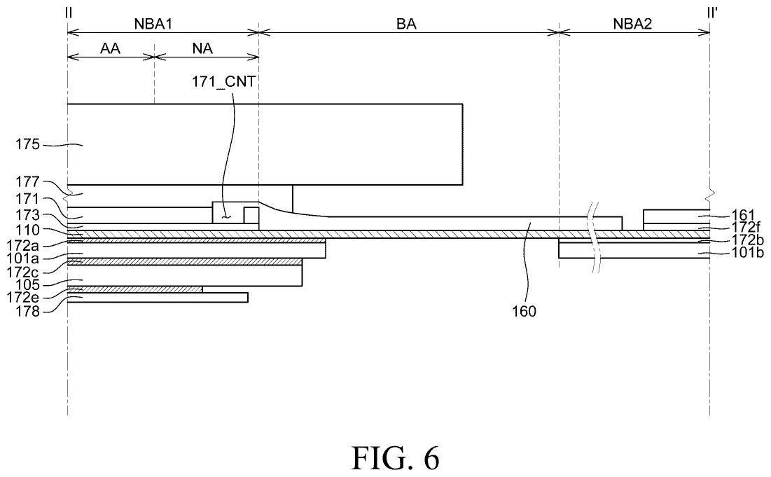

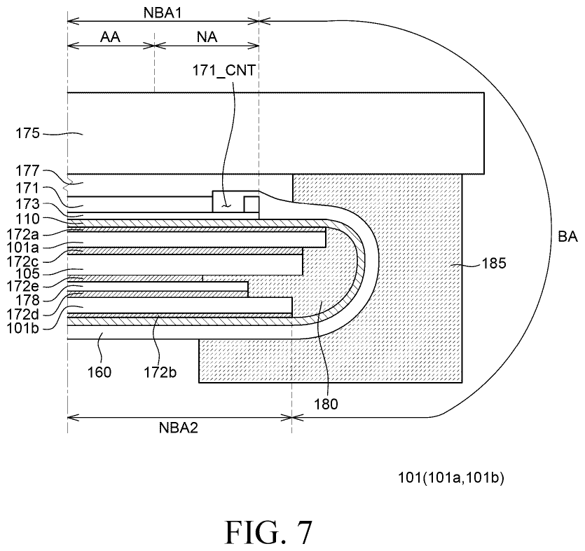

Hereinafter, a cross-sectional structure of the display device 100 which has been described in FIG. 2 will be described with reference to FIGS. 6 and 7, and specifically, a cross-sectional structure of the first non-active area between the active area AA and the bending area BA will be described.

FIG. 6 is a cross-sectional view taken along II-II′ of FIG. 2.

FIG. 7 is a cross-sectional view of a part of a display device according to an exemplary embodiment of the present disclosure.

Referring to FIG. 6, the display device 100 according to the exemplary embodiment of the present disclosure may include a polarization plate 171 and a cover member 175 disposed on a front surface (or a top surface) of the display panel 110.

The polarization plate 171 is disposed on the first non-bending area NBA1 of the display panel 110. The polarization plate 171 may be disposed so as to correspond to at least an active area AA to suppress reflection of external light above the active area AA. For example, external natural light is incident to the display device 100 and the incident light is reflected by a reflection layer included in the first electrode 510 of the light emitting diode 500 so that the image of the display device 100 may not be clearly visible. The polarization plate 171 may polarize the light entering from the outside to a specific direction and suppress the reflected light from being released to the outside of the display device 100. For example, the polarization plate 171 may be configured by a polarizer and a protection film which protects the polarizer or may be formed by coating a polarization material for the sake of flexibility.

On the first non-bending area NBA1, a first adhesive layer 173 is disposed between the polarization plate 171 and the display panel 110.

The first adhesive layer 173 may be configured to include a material having an adhesiveness and fix the polarization plate 171 above the first adhesive layer 173 to the display panel 110. For example, the first adhesive layer 173 may be configured by a pressure sensitive adhesive (PSA), but is not limited thereto. For example, the first adhesive layer 173 may be formed of an optical clear resin layer (OCR) or an optical clear adhesive film (OCA).

A second adhesive layer 177 may be interposed above the polarization plate 171 and a cover member 175 which protects an outer appearance of the display device 100 may be disposed above the second adhesive layer 177.

The second adhesive layer 177 may be configured to include a material having an adhesiveness and fix the cover member 175 above the second adhesive layer 177 to the polarization plate 171. For example, the second adhesive layer 177 may be formed of OCA and OCR, but is not limited thereto.

The cover member 175 protects components which configure the display device 100 including the display panel 110, from external shocks, moisture, and heat. The cover member 175 may be formed of a material having an impact resistance and optical transmittance. For example, the cover member 175 may be a substrate formed of glass or a film formed of a plastic material, such as polymethylmethacrylate (PMMA), polyimide (PI), or polyethylene terephthalate (PET), but is not limited thereto. Further, the cover member 175 may be referred to as various terminologies, such as a cover window, a window cover, or a cover glass, but is not limited thereto. In FIG. 6, it is illustrated that the cover member 175 is a quadrangular shape as an example, but the shape of the cover member 175 is not limited thereto. For example, a corner of a top surface of the cover member 175 which is exposed to the outside may have a predetermined curvature or an angle or a polygonal-shaped side surface to suppress the breakage.

Referring to FIG. 6, the display device 100 according to the exemplary embodiment of the present disclosure may include a back plate 101 on a back surface (or a rear surface) of the display panel 110 to support and protect the display panel 110.

The back plate 101 may be formed of a material having a rigidity and a high thermal conductivity. For example, the back plate 101 may be formed of a metal material such as aluminum (Al), copper (Cu), zinc (Zn), silver (Ag), gold (Au), iron (Fe), stainless steel (SUS), or invar or a material, such as plastic, but is not limited thereto.

The back plate 101 may include a first back plate 101a which is disposed on the rear surface of the display panel 110 in the first non-bending area NBA1 and a second back plate 101b which is disposed on the rear surface of the display panel 110 in the second non-bending area NBA2.

The first back plate 101a reinforces the rigidity of the flexible display panel 110 in accordance with the active area AA to support the first non-bending area NBA1 of the display panel 110 to maintain a flat state.

The second back plate 101b reinforces the rigidity of the flexible display panel 110 and the circuit element 161 to support the second non-bending area NBA2 of the display panel 110 to maintain a flat state.

The first back plate 101a and the second back plate 101b may be attached to the display panel 110 using the first and second adhesive members 172a and 172b, respectively. The first and second adhesive members 172a and 172b may be formed of a material having adhesiveness, and for example, be formed of OCA or PSA, but are not limited thereto.

Referring to FIG. 7, the display panel 110 may include a curved portion which is located between the first non-bending area NBA1 and the second non-bending area NBA2 and maintains a state bent at a predetermined curvature and the curved portion may correspond to the bending area BA. For example, the curved portion bent in the bending area BA may have a “⊃” shape, but is not limited thereto. For example, the curved portion may extend from the first non-bending unit NBA1 to be bent toward the rear direction at 180°so that the second non-bending unit NBA2 extending from the curved portion may be located so as to overlap the first non-bending unit NBA1 on the rear surface of the first non-bending unit NBA1. Therefore, in the second non-bending unit NBA2, illustrated in FIG. 6, the circuit element 161 attached to the display panel 110 by a sixth adhesive member 172f may also be located in the rear direction of the display panel 110 of the first non-bending unit NBA1, but is not limited thereto. The sixth adhesive member 172f may be formed of OCA or PSA, but is not limited thereto.

In order to ensure the flexibility of the curved portion of the display panel 110 and easily control a neutral plane using the first protection member 160 in the bending area BA, it is desirable that the back plate 101 is not located on the rear surface of the curved portion of the display panel 110.

Referring to FIG. 6, the support member 105 may be disposed on the rear surface of the first back plate 101a in the first non-bending area NBA1. The support member 105 may be bonded to the first back plate 101a by a third adhesive member 172c and be bonded to the second back plate 101b by a fourth adhesive member 172d. Referring to FIG. 7, in a state in which the bending area BA of the display panel 110 is bent, the support member 105 is disposed between the first back plate 101a and the second back plate 101b.

The support member 105 may be formed of a plastic material, such as a combination of polycarbonate (PC), polyimide (PI), polyethylene naphthalate (PEN), polyethylene terephthalate (PET), and polymers, but is not limited thereto. A strength of the support member 105 formed of the plastic materials as described above may be controlled by adding additives for increasing a thickness and strength of the support member 105. For example, the support member 105 may be formed of glass, ceramic, metal, other rigid materials, or a combination of the above-mentioned materials.

An additional barrier film 178 may be disposed between the support member 105 and the second back plate 101b.

The additional barrier film 178 may be configured to include a material having adhesiveness and serve as a buffer or a cushion. The additional barrier film 178 may be bonded to the support member 105 by a fifth adhesive member 172e, but is not limited thereto. For example, the additional barrier film 178 may be omitted.

In the meantime, in order to protect a connection line 140 disposed above the substrate 111 of the bending area BA when the substrate 111 is bent, as illustrated in FIGS. 6 and 7, a first protection member 160 is disposed on the substrate 111 in the bending area BA.

The gate signal, the data signal, and the touch driving signal which have been described above in FIGS. 1 to 5 are transmitted to the pixel P of the active area AA and the touch electrode 740R from the external module through the connection line 140. When the substrate 111 is bent, a part of the connection lines 140 disposed in the bending area BA is applied with a tensile stress. A part of the connection line 140 which extends in the same direction as the bending direction on the substrate 111 is affected by a large tensile stress so that the connection line 140 may be cracked or disconnected.

The first protection member 160 may suppress a crack of the connection line 140 and moisture permeation of the outside generated when the display panel 110 is bent. That is, the first protection member 160 may suppress the short-circuit problem of the connection line 140 due to an external shock applied to the bending area BA after being bent and/or the problem of permeation of external moisture and/or oxygen into the display panel 110.

The first protection member 160 may be a micro coating layer (MCL), but is not limited thereto. The first protection member 160 may include resin. For example, the first protection member 160 may use an ultraviolet ray (UV) curable acrylic resin or epoxy resin, but is not limited thereto.

The first protection member 160 may be disposed in a partial area of the first non-bending area NBA1 and/or a partial area of the second non-bending area NBA2 which is adjacent to the bending area BA.

The display device 100 according to the exemplary embodiment of the present disclosure may form an outer frame of the display device using a UV or thermal curable resin, instead of the existing metal frame, to reduce the bezel area.

Referring to FIG. 7, in a state in which the display panel 110 is bent, a second protection member 185 and a third protection member 180 may be disposed in the entire curved portion of the display panel 110 and a partial area adjacent to the bending area BA in the first and second non-bending areas NBA1 and NBA2.

The second protection member 185 is an external sealant and may be disposed in the form of frame around four edges of the display device 100, but is not limited thereto. In a state in which the display panel 110 is bent, the second protection member 185 may be disposed so as to cover one surface of the first protection member 160 which is exposed from a lower edge of the cover member 175. Further, the second protection member 185 may be disposed so as to cover a side surface of the adhesive layer 177 exposed to a lower edge of the cover member 175.

The third protection member 180 is an internal sealant and may be filled in an inner space of the display panel 110 which is bent at the lower edge of the display device 100, in a state in which the display panel 110 is bent.

For example, the second protection member 185 and the third protection member 180 may be configured by an epoxy mold. For example, the second protection member 185 and the third protection member 180 may be formed of a UV-curable material with added UV-curable oligomers, such as epoxy acrylate, urethane acrylate, polyester acrylate, urethane, urethane acrylate, or silicone acrylate, but are not limited thereto.

In the meantime, when the display device 100 according to the exemplary embodiment of the present disclosure is driven at a general temperature (for example, a room temperature), in a first non-active area between the active area AA and the bending area BA, a side surface (or an outermost portion) of the polarization plate 171 and a side surface (or an outermost portion) of the first adhesive layer 173 may be in contact with one end portion of the first protection member 160, respectively.

However, when the display device 100 is exposed in an environment in which a temperature change which exceeds a predetermined range occurs, the thermal expansion and contraction of the polarization plate 171 may be repeated. Accordingly, separation may occur in at least one between the side portion of the polarization plate 171 and one end of the first protection member 160 and between a side portion of the polarization plate 171 and a side portion of the second protection member 185 at the outer peripheral portion of the display panel 110. By doing this, a crack may occur from the outer peripheral portion of the display panel 110 in the first non-active area.

For example, during the manufacturing process, in order to evaluate a reliability for the display panel 110, the display device 100 may be exposed to a thermal cycle (TC) test environment in which extremely low temperatures and extremely high temperatures are periodically repeated. In such a TC test environment, a status change in which the polarization plate 171 is thermally expanded at a high temperature which exceeds a predetermined range and is contracted at a low temperature which is lower than a predetermined range is repeated so that the polarization plate 171 behaves in a horizontal direction. That is, in the extremely high temperature situation of the TC test environment, the polarization plate 171 is thermally expanded so that the outermost portion of the polarization plate 171 is affected by force toward the outside direction of the display panel 110. Further, in the extremely low temperature situation of the TC test environment, the polarization plate 171 is contracted so that the outermost portion of the polarization plate 171 is affected by force toward the inside direction of the display panel 110.

A coefficient of thermal expansion (CTE) of the polarization plate 171 is different from that of the other components of the display device 100, specifically, the display panel 110, the first protection member 160, and the second protection member 185. By doing this, during the process of repeating the thermal expansion and contraction of the polarization plate 171, the polarization plate 171 may be separated from the first protection member 160 and the second protection member 185 and thus a stress is applied to the display panel 110 to cause a crack.

For example, during the manufacturing process of the display device 100, in an initial state, in the first non-active area adjacent to the bending area BA, each of a side surface of the polarization plate 171 and a side surface of the first adhesive layer 173 may be in contact with a side surface of one end portion of the first protection member 160 to be bonded. Further, in the initial state, in the remaining first non-active area excluding an area adjacent to the bending area BA, each of the side surface of the polarization plate 171 and the side surface of the first adhesive layer 173 may be in contact with the side surface of the second protection member 185 to be bonded. At this time, the initial state refers to a state in which the status change caused by the repeated thermal expansion and contraction of the polarization plate 171 does not occur.

After such an initial state, when the display device 100 is exposed to the TC test environment so that the polarization plate 171 is repeatedly thermally expanded or contracted, the polarization plate 171 and the display panel 110 are bonded by means of the first adhesive layer 173. Therefore, when the polarization plate 171 is inwardly contracted or externally expanded, force caused by the contraction or expansion of the polarization plate 171 is periodically applied to the display panel 110. At this time, the display panel 110 has a coefficient of thermal expansion different from that of the polarization plate 171 so that the display panel 110 may resist the contraction force or expansion force of the polarization plate 171, which causes separation and cracks at the outer peripheral portion of the display panel 110. Further, when the polarization plate 171 is contracted to the inward direction of the display panel 110, the first protection member 160 and the second protection member 185 are also contracted to the outward direction of the display panel 110. By doing this, a side surface of each of the polarization plate 171 and the first adhesive layer 173 and a side surface of one end portion of the first protection member 160 may be separated and a side surface of each of the polarization plate 171 and the first adhesive layer 173 and a side surface of the second protection member 185 may be separated. When each of the first protection member 160 and the second protection member 185 and the polarization plate 171 and the first adhesive layer 173 are separated, a stress may be applied to the outer peripheral portion of the display panel 110, which causes a crack defect.

In order to suppress the separation generated between the polarization plate 171 and the first protection member 160 and between the polarization plate 171 and the second protection member 185 and the crack defect of the display panel 110 caused thereby due to the above-described reason, the polarization plate 171 of the display device 100 according to the exemplary embodiment of the present disclosure may include at least one contact hole 171_CNT at the outer peripheral portion.

Referring to FIGS. 6 and 7, one end portion of the first protection member 160 extends to a part of an area of the first non-active area (hereinafter, referred to as a “first area”) adjacent to the bending area BA to cover a contact hole 171_CNT at the outer peripheral portion of the polarization plate 171 to be filled in the contact hole 171_CNT. Accordingly, one end portion of the first protection member 160 may be hooked to the contact hole 171_CNT of the outer peripheral portion of the polarization plate 171 to be fastened and fixed.

For example, at least one contact hole 171_CNT is formed so as to pass through the polarization plate 171 and one end portion of the first protection member 160 which is filled in at least one contact hole 171_CNT may be in contact with the first adhesive layer 173 below the polarization plate 171. Accordingly, a contact area and a contact strength between the outer peripheral portion of the polarization plate 171 and one end portion of the first protection member 160 may be increased to suppress the separation.

When separation occurs between the side surface of the polarization plate 171 and one end portion of the first protection member 160, a force affecting the display panel 110 is concentrated in a portion where separation occurs so that stress on the display panel 110 is increased, which causes a crack. However, as described in the exemplary embodiment of the present disclosure, in a structure in which one end portion of the first protection member 160 is fastened to the outer peripheral portion of the polarization plate 171, the separation is suppressed. Further, a force affecting the display panel 110 is entirely dispersed on an adhered surface between the polarization plate 171 and the first protection member 160 to relieve the stress of the display panel 110 and suppress the crack.

Due to this, even in the temperature change environment in which thermal expansion and contraction of the polarization plate 171 are repeated, the effect on the other components by a force according to the behavior of the polarization plate 171 may be reduced. Accordingly, separation between the polarization plate 171 and the first protection member 160 is suppressed and a stress applied to the display panel 110 is relieved to suppress the cracks.

Further, in FIGS. 6 and 7, it is illustrated that the second adhesive layer 177 covers one end portions of the polarization plate 171 and the first protection member 160 and a side surface of the second adhesive layer 177 is located outwardly from the active area AA more than the side surface of the polarization plate 171 as an example. However, the present disclosure is not limited thereto. For example, the second adhesive layer 177 covers one end portions of the polarization plate 171 and the first protection member 160 and a side surface of the second adhesive layer 177 may be located on the same line as the side surface of the polarization plate 171.

In the display device 100 according to the exemplary embodiment of the present disclosure, the contact hole 171_CNT is a single contact hole which integrally extends along a boundary of the bending area BA and the first non-active area in the first area of the first non-active area. For example, as illustrated in FIG. 2, a bar-shaped contact hole 171_CNT may be located at the outer peripheral portion of the polarization plate 171 on the first area of the first non-active area of the display panel 110, but the shape and the placement structure of the contact hole 171_CNT are not limited thereto.

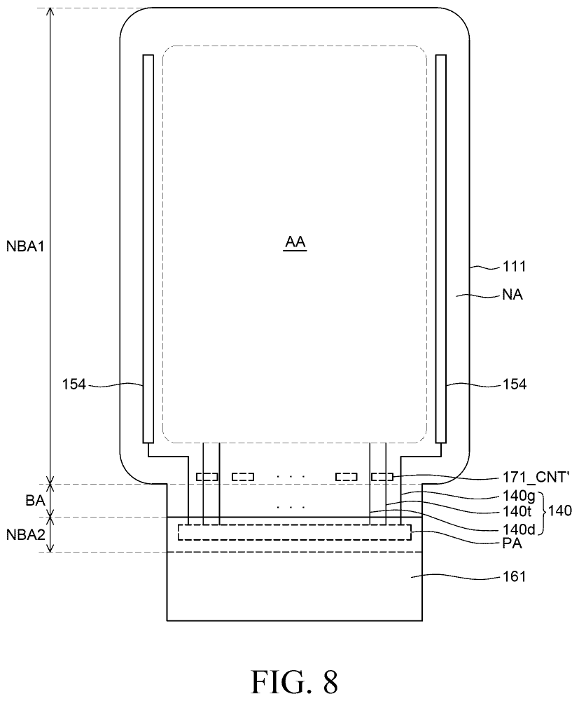

Hereinafter, another example of at least one contact hole 171_CNT included in the polarization plate 171 will be described with reference to FIG. 8.

FIG. 8 is a plan view of a display panel according to another exemplary embodiment of the present disclosure.

A display panel 110-1 according to another exemplary embodiment of the present disclosure illustrated in FIG. 8 is substantially the same as or similar to the display panel 110 which has been described above in FIGS. 1 to 7 except for a shape and a position of an area corresponding to a contact hole 171_CNT′ of the polarization plate 171. Therefore, a redundant description will be omitted.

Referring to FIG. 8, on the first area of the first non-active area of the display panel 110-1, an area in which a plurality of contact holes 171_CNT′ which is spaced apart from each other is formed may be located along a boundary of the bending area BA and the first non-active area. That is, on the first area of the first non-active area of the display panel 110-1, the plurality of contact holes 171_CNT′ which is spaced apart from each other is formed along a boundary of the bending area BA and the first non-active area at the outer peripheral portion of the polarization plate 171. For example, a shape of a horizontal cross-section of each of the plurality of contact holes 171_CNT′ may be a circle whose diameter is 0.1 mm and the plurality of contact holes 171_CNT′ may be spaced apart from each other with an interval of 0.3 mm, but the shape and the interval of the plurality of contact holes 171_CNT′ are not limited thereto.

In the first area of the first non-active area of the display panel 110-1 illustrated in FIG. 8, a vertical cross-section of the display device 100 corresponding to an area in which the plurality of contact holes 171_CNT′ is formed may be the same as or similar to a vertical cross-section of the display device 100 corresponding to an area in which the contact hole 171_CNT described above in FIGS. 6 and 7 is formed.

Further, in the first area of the first non-active area of the display panel 110-1 illustrated in FIG. 8, in an area of the polarization plate 171 in which the contact hole 171_CNT′ is not formed, one end portion of the first protection member 160 extends to a part of the first area to cover the outer peripheral portion of the polarization plate 171. Further, one end portion of the first protection member 160 and a top surface and a side surface of the polarization plate 171 may be in contact with each other.

As described above, on the first area of the first non-active area of the display panel 110-1, in a part of the outer peripheral portion of the polarization plate 171, one end portion of the first protection member 160 is filled in the plurality of contact holes 171_CNT′. In the other part of the outer peripheral portion of the polarization plate 171, a top surface and a side surface of the polarization plate 171 are entirely in contact with one end portion of the first protection member 160. Therefore, the adhesive strength and the adhered area between the outer peripheral portion of the polarization plate 171 and one end portion of the first protection member 160 are further increased to more efficiently suppress the separation between the polarization plate 171 and the first protection member 160.

Referring to FIG. 8, on the first area of the first non-active area of the display panel 110-1, each of the plurality of contact holes 171_CNT′ which is spaced apart from each other may overlap the touch connection line 140t. As described above, the plurality of contact holes 171_CNT′ which is spaced apart from each other is formed on the polarization plate 171 so as to overlap the touch connection line 140t. Accordingly, it is possible to more efficiently suppress the separation in a surrounding area of the touch connection line 140t in which a probability of cracks of the display panel 110-1 due to the separation is relatively higher than in the other areas, on the first area of the first non-active area.

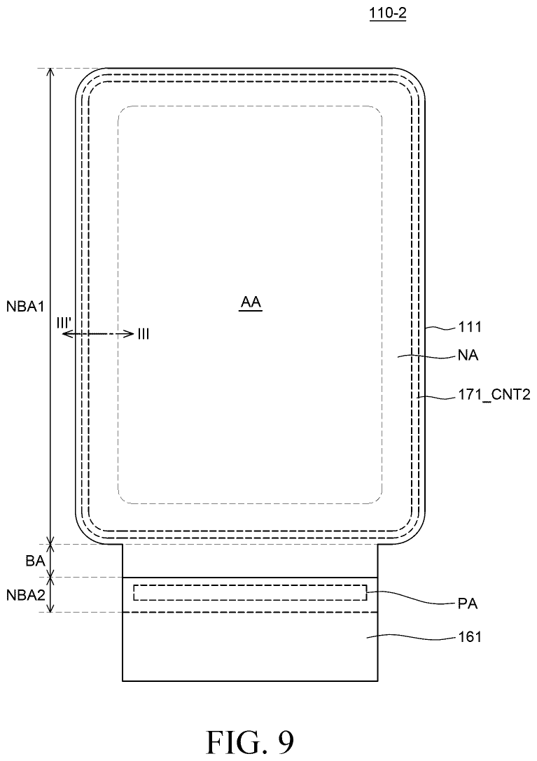

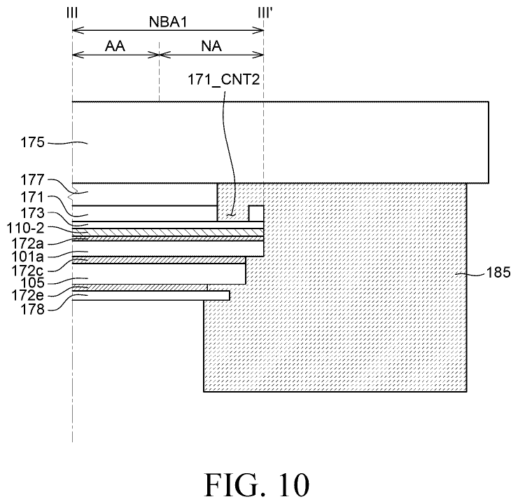

Hereinafter, still another example of at least one contact hole 171_CNT included in the polarization plate 171 in the display device 100 according to the exemplary embodiment of the present disclosure will be described with reference to FIGS. 9 and 10.

FIG. 9 is a plan view of a display panel according to still another exemplary embodiment of the present disclosure.

FIG. 10 is a cross-sectional view of another part of a display device according to an exemplary embodiment of the present disclosure.

A display panel 110-2 according to still another exemplary embodiment of the present disclosure illustrated in FIG. 9 is substantially the same as or similar to the display panel 110 which has been described above in FIGS. 1 to 7 except for a shape and a position of an area corresponding to a contact hole 171_CNT2 of the polarization plate 171. Therefore, a redundant description will be omitted.

Further, in a cross-sectional view of a display device according to an exemplary embodiment of the present disclosure, a remaining area of the first non-active area excluding a non-active area (that is, a first area) adjacent to the bending area BA is illustrated. Therefore, except for an area in which the first protection area 160 is not disposed, the display device includes components which are substantially the same as or similar to the components of the display device 100 which have been described above in FIGS. 6 and 7, but a redundant description will be omitted.

Referring to FIGS. 9 and 10 together, on a first non-active area of a display panel 110-2, an area in which a contact hole 171_CNT2 which integrally extends along a boundary of the active area AA and the non-active area NA is formed may be located. That is, the contact hole 171_CNT2 may be formed in the outer peripheral portion of the polarization plate 171 on the entire first non-active area of the display panel 110-2. For example, the contact hole 171_CNT2 may integrally extend along the external peripheral portion of the polarization plate 171 to be disposed as a closed loop shape which encloses the active area AA.

In the remaining area of the first non-active area (hereinafter, referred to as a “second area”) excluding the first area, a second protection member 185 covers side surfaces of the second adhesive layer 177, a polarization plate 171, a first adhesive layer 173, and a display panel 110-2 exposed from a lower edge of the cover member 175. Further, the second protection member 185 may cover exposed side surfaces of a back plate 101a, a support member 105, an additional barrier film 178, and adhesive members 172a, 172c, and 172e disposed on the rear surface of the display panel 110-2.

In the meantime, in the first area of the first non-active area of the display panel 110-2 illustrated in FIG. 9, a vertical cross-section of the display device 100 corresponding to an area in which the contact hole 171_CNT2 is formed may be the same as or similar to a vertical cross-section of the display device 100 corresponding to an area in which the contact hole 171_CNT described above in FIGS. 6 and 7 is formed.

Referring to FIG. 9, on a second area of a first non-active area of a display panel 110-2, an area in which a part of a contact hole 171_CNT2 which integrally extends along a boundary of the active area AA and the non-active area NA is formed may be located. That is, on the second area of the first non-active area of the display panel 110-2, a part of the contact holes 171_CNT2 is formed along a boundary of the active area AA and the non-active area NA in the outer peripheral portion of the polarization plate 171.

As described above, a part of the contact hole 171_CNT2 is formed in an outer peripheral portion of the polarization plate 171 on the second area of the first non-active area of the display panel 110-2. The remaining part of the contact hole 171_CNT2 is formed in an outer peripheral portion of the polarization plate 171 on the second area of the first non-active area of the display panel 110-2. Therefore, an integrated contact hole 171_CNT2 may be formed on the first area and the second area of the first non-active area.

In the meantime, referring to FIG. 10, on the second area of the first non-active area of the display panel 110-2, the second protection member 185 covers the contact hole 171_CNT2 in the outer peripheral portion of the polarization plate 171 to be filled in the contact hole 171_CNT2. Accordingly, a part of the second protection member 185 may be hooked to the contact hole 171_CNT2 of the outer peripheral portion of the polarization plate 171 to be fastened and fixed.

For example, the contact hole 171_CNT2 is formed so as to pass through the polarization plate 171 and a part of the second protection member 185 which is filled in the contact hole 171_CNT2 may be in contact with the first adhesive layer 173 below the polarization plate 171. Accordingly, an adhered area and an adhesive strength between the outer peripheral portion of the polarization plate 171 and the first protection member 160 may be increased to suppress the separation. By doing this, a force which affects the display panel 110-2 is entirely dispersed on the adhered surface between the polarization plate 171 and the second protection member 185 to relieve the stress of the display panel 110-2 and suppress the crack.

Due to this, even in the temperature change environment in which thermal expansion and contraction of the polarization plate 171 are repeated, the effect on the other components by a force according to the behavior of the polarization plate 171 may be reduced. Accordingly, separation between the polarization plate 171 and the second protection member 185 may be suppressed and a stress applied to the display panel 110-2 may be relieved to suppress the cracks.

Further, as illustrated in FIG. 10, the second adhesive layer 177 may cover a top surface of the polarization plate 171 and a side surface of the second adhesive layer 177 may be located inwardly to the active area AA more than the side surface of the polarization plate 171. For example, a side surface of the second adhesive layer 177 may be located by 100 m to 200 m inwardly from the side surface of the polarization plate 171, but is not limited thereto.

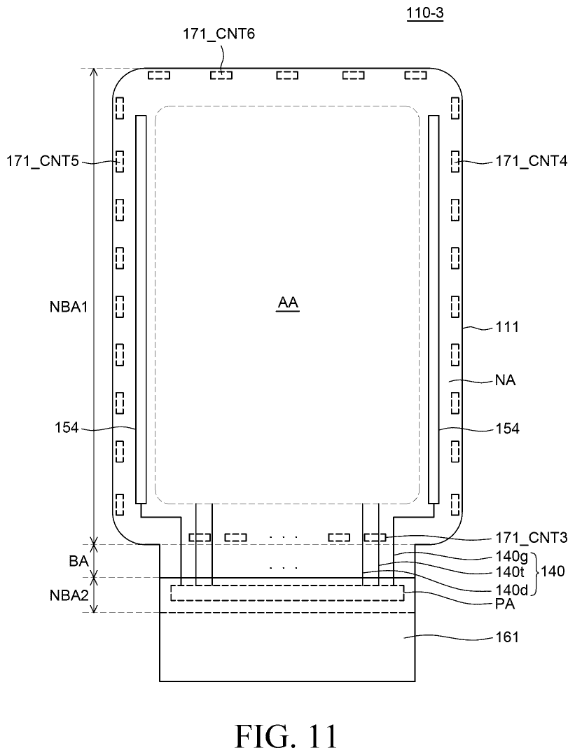

Hereinafter, still another example of at least one contact hole 171_CNT included in the polarization plate 171 in the display device 100 according to the exemplary embodiment of the present disclosure will be described with reference to FIG. 11.

FIG. 11 is a plan view of a display panel according to still another exemplary embodiment of the present disclosure.

A display panel 110-3 according to still another exemplary embodiment of the present disclosure illustrated in FIG. 11 is substantially the same as or similar to the display panel 110-2 which has been described above in FIGS. 9 to 10 except for a shape and a position of an area corresponding to contact holes 171_CNT3 to 171_CNT6 of the polarization plate 171. Therefore, a redundant description will be omitted.

Referring to FIG. 11, on a first non-active area of a display panel 110-3, an area in which a plurality of contact holes 171_CNT3 to 171_CNT6 which is spaced apart from each other is formed along a boundary of the active area AA and the non-active area NA may be located. That is, the plurality of contact holes 171_CNT3 to 171_CNT6 may be formed to be spaced apart from each other in the outer peripheral portion of the polarization plate 171 on the entire first non-active area of the display panel 110-3.

For example, on the first area of the first non-active area of the display panel 110-2, the plurality of first contact holes 171_CNT3 which is spaced apart from each other may be formed along a boundary of the bending area BA and the first non-active area in the outer peripheral portion of the polarization plate 171.

Further, on the second area of the first non-active area of the display panel 110-2, a plurality of second contact holes 171_CNT4 and a plurality of third contact hole 171_CNT5 which are spaced apart from each other is formed along the boundary of the active area AA and the non-active area NA in the outer peripheral portion of the polarization plate 171 on one side and the other side which are opposite to each other with the active area AA therebetween.

Further, on the second area of the first non-active area of the display panel 110-2, a plurality of fourth contact holes 171_CNT6 which is spaced apart from each other may be formed along the boundary of the active area AA and the non-active area NA in the outer peripheral portion of the polarization plate 171 on a side which is opposite to the bending area BA with the active area AA therebetween.

In the first area of the first non-active area of the display panel 110-3 illustrated in FIG. 11, a vertical cross-section of the display device 100 corresponding to an area in which the plurality of contact holes 171_CNT3 spaced apart from each other is formed may be the same as or similar to a vertical cross-section of the display device 100 corresponding to an area in which the contact hole 171_CNT2 described above in FIG. 10 is formed.

Further, in the first area of the first non-active area of the display panel 110-3 illustrated in FIG. 11, in an area of the polarization plate 171 in which a plurality of contact holes 171_CNT3 is not formed, one end portion of the first protection member 160 extends to a part of the first area to cover the outer peripheral portion of the polarization plate 171. Further, one end portion of the first protection member 160 and a top surface and a side surface of the polarization plate 171 may be in contact with each other. Further, in the second area of the first non-active area of the display panel 110-3 illustrated in FIG. 11, in an area of the polarization plate 171 in which a plurality of contact holes 171_CNT4 to 171_CNT5 is not formed, a part of the second protection member 185 extends to a part of the second area to cover the outer peripheral portion of the polarization plate 171. Further, a part of the second protection member 185 and a top surface and a side surface of the polarization plate 171 may be in contact with each other.

As described above, on the second area of the first non-active area of the display panel 110-3, in a part of the outer peripheral portion of the polarization plate 171, a part of the second protection member 185 is filled in the plurality of contact holes 171_CNT3. In the other part of the outer peripheral portion of the polarization plate 171, a top surface and a side surface of the polarization plate 171 are entirely in contact with a part of the second protection member 185. Therefore, the adhesive strength and the adhered area between the outer peripheral portion of the polarization plate 171 and the second protection member 185 are further increased to more efficiently suppress the separation between the polarization plate 171 and the second protection member 185.

As detailed above, the present disclosure describes a two zone edge reinforcement approach for a flexible display device, centered on contact hole fastening in the polarizing plate (171). In the first area near the bend, a first protection member (180a) extends from the bend into the non active region and fills first contact holes (171_CNT) in the polarizing plate. These holes may be continuous in the form of a bar or may be spaced holes such as 0.1 mm diameter with 0.3 mm spacing, and may be aligned with crack prone touch connection lines. The filled resin may also contact the first adhesive layer beneath the polarizing plate, which increases bonded area and reduces separation caused by thermal expansion mismatch. This structure directly addresses stress concentrations at the bend and improves durability during thermal cycling.

In the second area around the remaining periphery, the polarizing plate includes second contact holes (171_CNT2) that are filled by a second protection member (190a). These holes can form a continuous closed loop or can be arranged as plural spaced holes, and in some embodiments they allow the second protection member to contact the first adhesive layer. Additional edge conditions are described: in the first area the second adhesive layer can cover the end of the first protection member and may align with or extend past the polarizing plate edge, while in the second area the second adhesive layer is positioned slightly inboard for example 100 to 200 micrometers, which optimizes edge constraint. These features contribute mechanical interlock, added adhesion, and stress dispersion, thereby reducing edge separation and cracking.

The display device also uses a third protection member (190b) that fills the inner space at the bent lower edge, while a back plate is omitted across the curved portion to preserve flexibility and favorable neutral plane placement. The specification indicates that each of the disclosed features—contact holes in the polarizing plate filled by protection members, specific hole geometries and placements, and adhesive edge configurations—provides stress relief or adhesion improvements individually. In various embodiments one or more of these measures may be employed, and when applied together they offer complementary reinforcement against the identified failure mode of delamination and panel cracking caused by polarizing plate edge separation.

The exemplary embodiments of the present disclosure can also be described as follows:

According to an aspect of the present disclosure, there is provided a display device. The display device includes a display panel which includes a non-bending area including an active area in which a plurality of light emitting diodes is disposed and a non-active area which encloses the active area and a bending area extending from one side of the non-active area. The display device further includes a polarization plate disposed on the display panel in the non-bending area. The display device further includes a first adhesive layer disposed between the display panel and the polarization plate in the non-bending area. The display device further includes a first protection member disposed on the display panel in the bending area. The polarization plate includes at least one first contact hole in a first area of the non-active area between the active area and the bending area and one end portion of the first protection member extends to a part of the first area to be filled in the at least one first contact hole.

The at least one first contact hole may be a single contact hole which integrally extends along a boundary of the bending area and the non-active area.

The at least one first contact hole may be a plurality of contact holes which is spaced apart from each other along a boundary of the bending area and the non-active area.

The one end portion of the first protection member may be in contact with the first adhesive layer through the at least one first contact hole.

A side surface of the polarization plate and a side surface of the first adhesive layer may be in contact with the first protection member.

The display device may further include: a cover member disposed on the polarization plate; a second adhesive layer disposed between the cover member and the polarization plate; and a second protection member which is disposed so as to cover one surface of the first protection member exposed from a lower edge of the cover member. The polarization plate may further include at least one second contact hole in a second area of the non-active area excluding the first area and the second protection member is filled in the at least one second contact hole.

The at least one second contact hole may be a single contact hole which integrally extends along a boundary of the active area and the non-active area.

The at least one second contact hole is a plurality of contact holes which is spaced apart from each other along a boundary of the active area and the non-active area.

A part of a side surface of the second protection member may be in contact with the first adhesive layer through the at least one second contact hole.

In the second area, side surfaces of the second adhesive layer, the polarization plate, the first adhesive layer, and the display panel may be in contact with a side surface of the second protection member.

In the bending area, the one surface of the first protection member and a side surface of the second adhesive layer may be in contact with the second protection member and the other surface which is opposite to the one surface of the first protection member is in contact with the display panel.

In the first area, the second adhesive layer may cover the one end portion of the first protection member.

In the first area, a side surface of the second adhesive layer may be on the same line as a side surface of the polarization plate or be located outward from the active area more than the side surface of the polarization plate.

In the second area, a side surface of the second adhesive layer may be located inward to the active area more than a side surface of the polarization plate.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a non-bending area and a bending area, the non-bending area including an active area in which a plurality of light emitting diodes is disposed and a non-active area adjacent to the active area, and the bending area extending from one side of the non-active area;
a polarization plate disposed on the display panel in the non-bending area;
a first adhesive layer disposed between the display panel and the polarization plate in the non-bending area;
a first protection member disposed on the display panel in the bending area; and
at least one first contact hole disposed in a first area of the non-active area of the polarizing plate, the first area being between the active area and the bending area,
wherein one end portion of the first protection member extends to a part of the first area, and
wherein the one end portion of the first protection member extends into the at least one first contact hole.

2. The display device according to claim 1, wherein the at least one first contact hole is a single contact hole integrally extending along a boundary of the bending area and the non-active area.

3. The display device according to claim 1, wherein the at least one first contact hole is a plurality of contact holes spaced apart from each other along a boundary of the bending area and the non-active area.

4. The display device according to claim 1, wherein the one end portion of the first protection member is in contact with the first adhesive layer through the at least one first contact hole.

5. The display device according to claim 1, wherein a side surface of the polarization plate and a side surface of the first adhesive layer are in contact with the first protection member.

6. The display device according to claim 1, further comprising:
a cover member disposed on the polarization plate;
a second adhesive layer disposed between the cover member and the polarization plate; and
a second protection member disposed to cover one surface of the first protection member that is exposed at an edge of the cover member,
wherein the polarization plate further includes at least one second contact hole in a second area of the non-active area excluding the first area, and
wherein the second protection member is present in the at least one second contact hole.

7. The display device according to claim 6, wherein the at least one second contact hole is a single contact hole integrally extending along a boundary of the active area and the non-active area.

8. The display device according to claim 6, wherein the at least one second contact hole is a plurality of contact holes spaced apart from each other along a boundary of the active area and the non-active area.

9. The display device according to claim 6, wherein at least a portion of a side surface of the second protection member is in contact with the first adhesive layer through the at least one second contact hole.

10. The display device according to claim 6, wherein in the second area, side surfaces of the second adhesive layer, the polarization plate, the first adhesive layer, and the display panel are each in contact with a side surface of the second protection member.

11. The display device according to claim 6, wherein, in the bending area, a surface of the first protection member that faces the second adhesive layer is in contact with the second protection member, and
a surface of the first protection member opposite to the surface that faces the second adhesive layer is in contact with the display panel.

12. The display device according to claim 6, wherein in the first area, the second adhesive layer covers the one end portion of the first protection member.

13. The display device according to claim 12, wherein in the first area, a side surface of the second adhesive layer is flush with a side surface of the polarization plate or is located outward from the active area more than the side surface of the polarization plate.

14. The display device according to claim 6, wherein in the second area, a side surface of the second adhesive layer is positioned closer to the active area more than a side surface of the polarization plate.
